(19) United States
(12) Patent Application Publication
(10) Pub. No.: US 2024/0194460 A1
(43) Pub. Date: Jun. 13, 2024

(54) ADVANCED DRY CLEANING APPARATUS AND METHOD FOR DRIVE DEVICE

(71) Applicant: LC Tech Co., Ltd., Suwon-si (KR)

(72) Inventors: Jong Hwan KIM, Busan (KR); Jeong Min HAN, Seoul (KR); In Soo JEON, Busan (KR); Dae Seok PARK, Anseong-si (KR); Ji Yeon KIM, Yongin-si (KR)

(21) Appl. No.: 18/517,273

(22) Filed: Nov. 22, 2023

(30) Foreign Application Priority Data
Dec. 13, 2022 (KR) 10-2022-0173939
Jun. 15, 2023 (KR) 10-2023-0076825
Jul. 28, 2023 (KR) 10-2023-0099077

(51) Int. Cl. H01J 37/32; H01L 21/67

(52) U.S. Cl. CPC H01J 37/32853; H01J 37/32449; H01L 21/67051; H01L 21/67276

(57) ABSTRACT

A dry cleaning apparatus includes a drive IC separating unit configured to separate a drive device from a display panel or a flexible printed circuit board, a first cleaning unit configured to remove residues of an anisotropic conductive film by performing CO₂ cleaning on the drive device, a second cleaning unit configured to remove residues of the anisotropic conductive film by performing atmospheric pressure plasma cleaning on the drive device, and a surface inspecting unit configured to perform surface inspection on the drive device after the CO₂ cleaning or the atmospheric pressure plasma cleaning.

### CROSS-REFERENCE TO RELATED APPLICATION

This application claims priority to and the benefit of Korean Patent Application No. 10-2023-0076825 filed in the Korean Intellectual Property Office on Jun. 15, 2023, Korean Patent Application No. 10-2022-0173939 filed in the Korean Intellectual Property Office on Dec. 13, 2022, and Korean Patent Application No. 10-2023-0099077 filed in the Korean Intellectual Property Office on Jul. 28, 2023, the entire contents of which are incorporated herein by reference.

### BACKGROUND

### (a) Field

Embodiments of the present disclosure relates to an advanced dry cleaning apparatus and method for a drive device, and more particularly, to an advanced dry cleaning apparatus and method, which are capable of recycling a drive IC by removing an anisotropic conductive film remaining on the drive IC at the time of separating the drive IC from a display panel to recycle the drive IC.

### (b) Description of the Related Art

A display device includes a display panel configured to display an image, a gate drive part configured to operate the display panel, and a data drive part configured to operate the display panel. The gate drive part applies gate signals to gate lines connected to a plurality of pixels, and the data drive part applies data voltages to data lines connected to the plurality of pixels.

The data drive part and the gate drive part may be provided as separate integrated circuit chips (IC chips). The data drive part and the gate drive part may be mounted on a flexible printed circuit board (FPCB) and electrically connected to the display panel or mounted directly on the display panel.

A display drive IC (DDI) (hereinafter, referred to as a ‘drive IC’), such as the data drive part and the gate drive part, may be electrically connected to an electrode pad of a display panel or a flexible printed circuit board by means of an anisotropic conductive film (ACF).

In case that a defect occurs during a process of manufacturing a display device, the drive IC is separated from the display panel and recycled (or recoupled), thereby improving a production yield. In the related art, as a method of removing the anisotropic conductive film after the drive IC is separated from the display panel by heat and a physical force, there has been used a cleaning method of using a chemical solution (i.e., an ACF remover) to soften the anisotropic conductive film and using a cotton swab or a bamboo stick to remove the softened anisotropic conductive film. The cleaning method is performed by applying the ACF remover onto a cleaning portion to be cleaned, leaving the cleaning portion unattended for several minutes to several tens of minutes until the anisotropic conductive film is softened, scraping the softened anisotropic conductive film with a cotton swab or a bamboo stick, and wiping the softened anisotropic conductive film with a cotton swab dipped in a dedicated cleaning liquid. For example, the cleaning portion is left unattended for 3 to 5 minutes after the ACF remover is applied onto the cleaning portion, the applied ACF remover is wiped out by a cotton swab dipped in a dedicated cleaning liquid, the softened anisotropic conductive film is scraped by the cotton swab or the bamboo stick, and the softened anisotropic conductive film is finally wiped out by the cotton swab dipped in the dedicated cleaning liquid. This cleaning method is a cleaning method that may be applied only to the separated display panel and the flexible printed circuit board, but this cleaning method cannot be applied to clean a bump surface of the drive IC and a flexible display panel.

Recently, sizes of electrode pads, sizes of bumps of the drive IC, intervals between the electrode pads, and intervals between the bumps have been reduced to minimize a bezel of the display device. The cleaning method of cleaning the display device in the related art, which softens the anisotropic conductive film by using the chemical solution and scraps and wipes out the anisotropic conductive film by using the physical tools, cannot completely remove the anisotropic conductive film, and the cleaning method may provide physical contact that may cause damage to the electrode pad and the bump of the drive IC.

Because a substrate of the flexible display panel is made of plastic, the cleaning method in the related art, which causes the substrate to be in contact with the ACF remover over a long period of time, cannot remove residues of the anisotropic conductive film of the display panel.

The cleaning method in the related art requires a large amount of cleaning time and inevitably depends on a manual operation, which makes it difficult to ensure automation and mass production. Further, chemical agents, such as the ACF remover and the dedicated cleaning liquid, need to be used, which may cause harmfulness to human bodies and environmental problems.

### SUMMARY

Embodiments of the present disclosure attempts to provide a dry cleaning apparatus and method capable of removing, in a contactless and dry manner, an anisotropic conductive film remaining on a drive IC at the time of separating the drive IC from a display panel to recycle the drive IC.

An exemplary embodiment of the present disclosure provides a dry cleaning apparatus including: a drive IC separating unit configured to separate a drive device from a display panel or a flexible printed circuit board; a first cleaning unit configured to remove residues of an anisotropic conductive film by performing CO₂ cleaning on the drive device; a second cleaning unit configured to remove residues of the anisotropic conductive film by performing atmospheric pressure plasma cleaning on the drive device; and a surface inspecting unit configured to perform surface inspection on the drive device after the CO₂ cleaning or the atmospheric pressure plasma cleaning.

The surface inspecting unit may determine quality product determination when the amount of residues remaining on the drive device is equal to or less than a preset reference value, and the surface inspecting unit may determine defective product determination or additional cleaning determination when the amount of residues remaining on the drive device exceeds the reference value.

The surface inspecting unit may determine the additional cleaning determination until the number of times of cleaning reaches a predetermined number of times of cleaning, and the surface inspecting unit may finally determine the drive device as a defective product when the amount of residues remaining on the drive device exceeds the reference value even when the number of times the CO₂ cleaning and the atmospheric pressure plasma cleaning are performed reaches the number of times of cleaning.

The drive IC separating unit may include: a drive IC stage configured to suck and transfer the drive device and fix the drive device at the time of cleaning the drive device; and a laser source configured to selectively combust adhesive resin included in the anisotropic conductive film by emitting laser beams having a high absorption rate to the adhesive resin.

The first cleaning unit may include: a first sprayer configured to spray solid dry ice particles and carrier gas at a height from a surface of the drive device in a vertical direction.

The second cleaning unit may include: a second sprayer configured to discharge atmospheric pressure plasma at a height from a surface of the drive device in a vertical direction.

Another exemplary embodiment of the present disclosure provides a dry cleaning method including: separating, by a drive IC separating unit, a drive device from a display panel or a flexible printed circuit board; removing, by a first cleaning unit, residues of an anisotropic conductive film by performing CO₂ cleaning on the drive device; performing, by a surface inspecting unit, first surface inspection on the drive device after the CO₂ cleaning; removing, by a second cleaning unit, residues of the anisotropic conductive film by performing atmospheric pressure plasma cleaning on the drive device; and performing, by a surface inspecting unit, second surface inspection on the drive device after the atmospheric pressure plasma cleaning.

The CO₂ cleaning may be repeatedly performed when the amount of residues remaining on the drive device exceeds a preset first reference value during the first surface inspection.

The surface inspecting unit may determine the drive device as a quality product when the amount of residues remaining on the drive device is equal to or less than a preset second reference value in the second surface inspection, and the surface inspecting unit may additionally perform the CO₂ cleaning or the atmospheric pressure plasma cleaning when the amount of residues remaining on the drive device exceeds the second reference value.

The separating of the drive device may include selectively combusting adhesive resin included in the anisotropic conductive film by emitting laser beams having a high absorption rate to the adhesive resin.

The removing of the residues of the anisotropic conductive film by performing the CO₂ cleaning on the drive device may include removing residues of the anisotropic conductive film by spraying solid dry ice particles and carrier gas at a height from a surface of the drive device in a vertical direction.

The removing of the residues of the anisotropic conductive film by performing the atmospheric pressure plasma cleaning on the drive device may include removing residues of the anisotropic conductive film by discharging atmospheric pressure plasma at a height from a surface of the drive device in a vertical direction.

Still another exemplary embodiment of the present disclosure provides a dry cleaning method including: separating, by a drive IC separating unit, a drive device from a display panel or a flexible printed circuit board; removing, by a first cleaning unit, residues of an anisotropic conductive film by performing CO₂ cleaning on the drive device and then removing, by a second cleaning unit, residues of the anisotropic conductive film by performing atmospheric pressure plasma cleaning on the drive device; and performing, by a surface inspecting unit, surface inspection on the drive device.

Yet another exemplary embodiment of the present disclosure provides a dry cleaning method including: separating, by a drive IC separating unit, a drive device from a display panel or a flexible printed circuit board; removing, by a first cleaning unit, residues of an anisotropic conductive film by performing first CO₂ cleaning on the drive device; removing, by a second cleaning unit, residues of the anisotropic conductive film by performing atmospheric pressure plasma cleaning on the drive device; removing, by the first cleaning unit, residues of the anisotropic conductive film by performing second CO₂ cleaning on the drive device; and performing, by a surface inspecting unit, surface inspection on the drive device.

A further exemplary embodiment of the present disclosure provides a dry cleaning method including: separating, by a drive IC separating unit, a drive device from a display panel or a flexible printed circuit board; removing, by a second cleaning unit, residues of an anisotropic conductive film by performing atmospheric pressure plasma cleaning on the drive device and then removing, by a first cleaning unit, residues of the anisotropic conductive film by performing CO₂ cleaning on the drive device; and performing, by a surface inspecting unit, surface inspection on the drive device.

Another further exemplary embodiment of the present disclosure provides a dry cleaning method including: separating, by a drive IC separating unit, a drive device from a display panel or a flexible printed circuit board; removing, by a cleaning unit, residues of an anisotropic conductive film by performing atmospheric pressure plasma cleaning on the drive device; and performing, by a surface inspecting unit, surface inspection on the drive device, determining quality product determination when the amount of residues remaining on the drive device is equal to or less than a preset reference value, and determining defective product determination or additionally performing the atmospheric pressure plasma cleaning when the amount of residues remaining on the drive device exceeds the reference value.

The anisotropic conductive film, which remains when the display panel and the drive IC are separated, may be removed in a contactless and dry manner, and thus the display panel and the drive IC may be recycled, thereby solving the problem of economical losses and environmental issues caused when the display panel and the drive IC are discarded.

### BRIEF DESCRIPTION OF THE DRAWINGS

FIG. 1 is a top plan view schematically illustrating a display device according to an embodiment.

FIG. 2 is a cross-sectional view illustrating a cross-section of the display device according to an embodiment taken along line II-II′ in FIG. 1.

FIG. 3 is a block diagram illustrating a dry cleaning apparatus for recycling a drive IC according to the embodiment of the present disclosure.

FIG. 4 is a flowchart illustrating a method of performing a process of separating the drive IC according to the embodiment of the present disclosure.

FIGS. 5 and 6 are cross-sectional views for explaining the method of performing the process of separating the drive IC according to the embodiment of the present disclosure.

FIG. 7 is a flowchart illustrating a method of performing a CO₂ cleaning process according to the embodiment of the present disclosure.

FIG. 8 is a cross-sectional view for explaining the method of performing the CO₂ cleaning process according to the embodiment of the present disclosure.

FIG. 9 is a flowchart illustrating a method of performing an atmospheric pressure plasma cleaning process according to the embodiment of the present disclosure.

FIG. 10 is a cross-sectional view for explaining the method of performing the atmospheric pressure plasma cleaning process according to the embodiment of the present disclosure.

FIG. 11 is a flowchart illustrating a dry cleaning method for recycling a drive IC according to the embodiment of the present disclosure.

FIG. 12 is a flowchart illustrating a dry cleaning method for recycling a drive IC according to another embodiment of the present disclosure.

FIG. 13 is a flowchart illustrating a dry cleaning method for recycling a drive IC according to still another embodiment of the present disclosure.

FIG. 14 is a flowchart illustrating a dry cleaning method for recycling a drive IC according to yet another embodiment of the present disclosure.

FIG. 15 is a flowchart illustrating a dry cleaning method for recycling a drive IC according to still yet another embodiment of the present disclosure.

### DETAILED DESCRIPTION

Hereinafter, embodiments of the present disclosure will be described in detail with reference to the accompanying drawings so that those with ordinary skill in the art to which the present disclosure pertains may easily carry out the embodiments. The present disclosure may be implemented in various different ways and is not limited to the embodiments described herein.

In addition, the constituent elements having the same configurations in the several embodiments will be assigned with the same reference numerals and described representatively in a first embodiment, and only the constituent elements, which are different from the constituent elements according to the first embodiment, will be described in other embodiments.

A part irrelevant to the description will be omitted to clearly describe the present disclosure, and the same or similar constituent elements will be designated by the same reference numerals throughout the specification.

A size and thickness of each constituent element illustrated in the drawings are arbitrarily shown for convenience of description, but the present disclosure is not limited thereto. In order to clearly describe several layers and regions, thicknesses thereof are enlarged in the drawings. In the drawings, the thicknesses of some layers and regions are exaggerated for convenience of description.

When one component such as a layer, a film, an area, or a plate is described as being positioned “above” or “on” another component, one component can be positioned “directly on” another component, and one component can also be positioned on another component with other components interposed therebetween. On the contrary, when one component is described as being positioned “directly above” another component, there is no component therebetween. In addition, when a component is described as being positioned “above” or “on” a reference part, the component may be positioned “above” or “below” the reference part, and this configuration does not necessarily mean that the component is positioned “above” or “on” the reference part in a direction opposite to gravity.

Throughout the specification, unless explicitly described to the contrary, the word “comprise/include” and variations such as “comprises/includes” or “comprising/including” will be understood to imply the inclusion of stated elements, not the exclusion of any other elements.

Throughout the specification, the phrase “in a plan view” means when an object is viewed from above, and the phrase “in a cross-sectional view” means when a cross section made by vertically cutting an object is viewed from a lateral side.

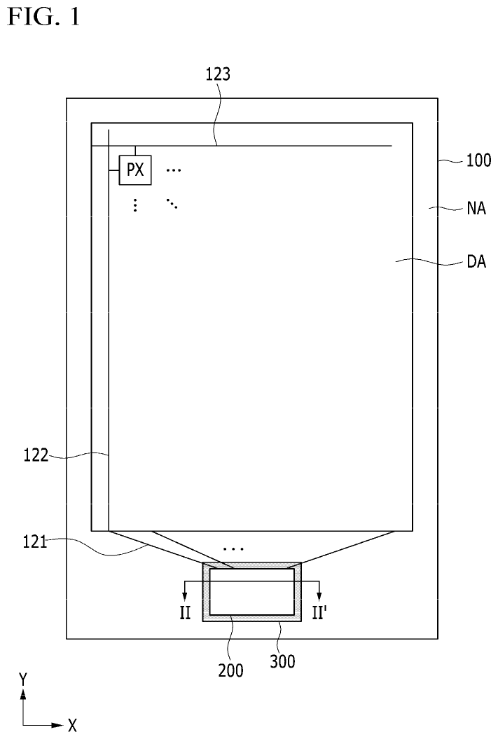

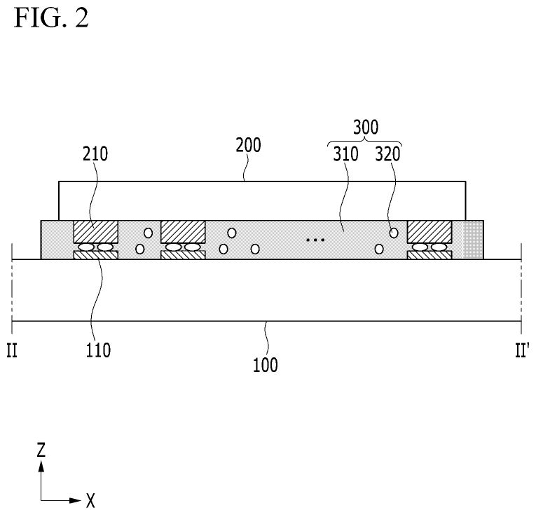

Hereinafter, a display device according to an embodiment will be described with reference to FIGS. 1 and 2.

FIG. 1 is a top plan view schematically illustrating a display device according to an embodiment. FIG. 2 is a cross-sectional view illustrating a cross-section of the display device according to an embodiment taken along line II-II′ in FIG. 1.

With reference to FIGS. 1 and 2, the display device according to the embodiment may include a substrate 100, a drive IC 200, and an anisotropic conductive film 300. The anisotropic conductive film 300 serves to join the substrate 100 and the drive IC 200.

The substrate 100 may include a display area DA and a non-display area NA. The substrate 100 may be made of plastic characterized by having high heat resistance, electrical insulation, flexibility, non-flexibility, and the like. For example, the substrate 100 may be made of synthetic resin such as polyimide (PI).

The display area DA refers to an area that displays images and includes a plurality of pixels PX arranged in a first direction X and a second direction Y, and a plurality of data lines 122 and a plurality of gate lines 123 connected to the plurality of pixels PX. In a plan view, the plurality of gate lines 123 may extend in the first direction X, and the plurality of data lines 122 may extend in the second direction Y. The second direction Y may be orthogonal to the first direction X.

The non-display area NA refers to an area in which the drive IC 200 is mounted and lines or circuits for applying signals to the plurality of pixels PX are disposed. The non-display area NA refers to an area that displays no image. The non-display area NA surrounds the display area DA.

The drive IC 200 may be disposed in the non-display area NA. Pan-out lines 121 connected to the display area DA from the drive IC 200 may be disposed in the non-display area NA. The pan-out lines 121 may connect the drive IC 200 and the plurality of data lines 122. The drive IC 200 may be a data drive part that applies data voltages to the plurality of pixels PX through the data lines 122. In this case, the example has been described in which the drive IC 200 is the data drive part. However, according to the embodiment, the drive IC 200 may serve as a gate drive part connected to the plurality of gate lines 123 and configured to apply gate signals. Alternatively, the drive IC 200 may serve to apply signals such as light-emitting signals or power voltages to signal lines such as light-emitting signal lines (not illustrated) or voltage lines (not illustrated) connected to the plurality of pixels PX.

A plurality of pads 110 is formed in the non-display area NA and applies driving signals to the plurality of pixels PX. The signals, the voltages, and the like may be applied to the data line 122s, the gate lines 123, the light-emitting signal lines, the voltage lines, and the like connected to the plurality of pixels PX through the plurality of pads 110. The plurality of pads 110 may be arranged on the substrate 100. The arrangement direction and the arrangement pattern of the plurality of pads 110 are not limited. The plurality of pads 110 may be made of metal such as copper (Cu), molybdenum (Mo), aluminum (Al), silver (Ag), platinum (Pt), palladium (Pd), chromium (Cr), tantalum (Ta), or titanium (Ti), or an alloy thereof.

The display panel may be a flexible display panel and include the substrate 100 on which the plurality of pixels PX and various types of lines are formed.

The drive IC 200 may be mounted on the plurality of pads 110 (in a third direction Z). The drive IC 200 includes a plurality of bumps 210 formed on a bottom surface thereof. The drive IC 200 may be electrically connected to the plurality of pads 110 through the plurality of bumps 210. The plurality of bumps 210 may be positioned on the plurality of pads 110 and overlap the plurality of pads 110.

The substrate 100 and the drive IC 200 may be joined by the anisotropic conductive film 300. The anisotropic conductive film 300 may include adhesive resin 310 configured in a film state, and conductive particles 320 distributed in the adhesive resin 310. The adhesive resin 310 may be made of an epoxy-based material. The conductive particle 320 may have a basic structure made by coating polymer with a metal film, and an insulation film may be additionally applied to the metal film. The metal film may be made of metal such as nickel (Ni), aluminum (Al), copper (Cu), lead (Pb), silver (Ag), or gold (Au), or an alloy thereof. The conductive particle 320 may have various shapes such as a spherical shape, a shape having protrusions formed on a spherical surface, or a metal piece shape having a fragmentary structure having a sharp external shape.

The drive IC 200 may be joined to the substrate 100 by applying heat and pressure for a predetermined time after the anisotropic conductive film 300 is disposed between the substrate 100 and the drive IC 200. In this case, the conductive particles 320 positioned between the plurality of bumps 210 of the drive IC 200 and the plurality of pads 110 of the substrate 100 may be electrically connected to the plurality of bumps 210 of the drive IC 200 and the plurality of pads 110 of the substrate 100.

In this case, the example has been described in which the drive IC 200 is mounted in the non-display area NA of the substrate 100. However, according to the embodiment, the drive IC 200 may be mounted on a flexible printed circuit board (FPCB), and the flexible printed circuit board may be electrically connected to the display panel. In addition, an example will be described in which the drive IC 200 is separated from the display panel. This example may be applied in the same way to a case in which the drive IC 200 is separated from the flexible printed circuit board.

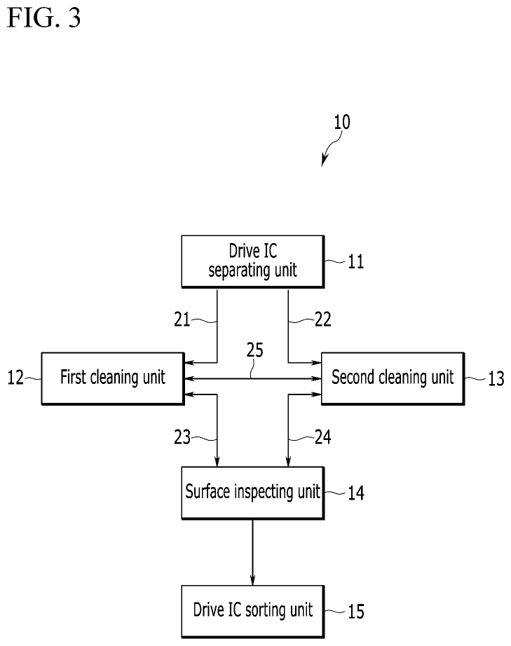

Hereinafter, the dry cleaning apparatus and method for the drive device according to the embodiment of the present disclosure will be described with reference to FIGS. 3 to 10. Hereinafter, an apparatus and method for dry-cleaning the drive IC 200 of the display device will be described as an example. However, the dry cleaning apparatus and method according to the embodiment of the present disclosure may be applied to clean various types of semiconductors, displays, and electronic components. The drive IC 200, the semiconductor, the display, the electronic component, and the like, which are objects to be dry-cleaned, may be collectively called the drive device.

FIG. 3 is a block diagram illustrating a dry cleaning apparatus for recycling a drive IC according to the embodiment of the present disclosure.

With reference to FIG. 3, a dry cleaning apparatus 10 for recycling a drive IC may include a drive IC separating unit 11, a first cleaning unit 12, a second cleaning unit 13, a surface inspecting unit 14, and a drive IC sorting unit 15.

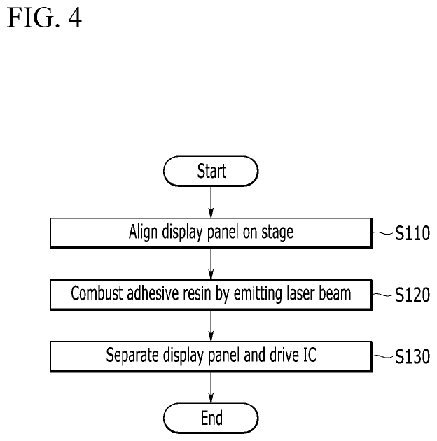

The drive IC separating unit 11 may perform a drive IC separating process of separating the drive IC 200 from the display panel or the flexible printed circuit board. The drive IC separating process will be described below in detail with reference to FIGS. 4 to 6.

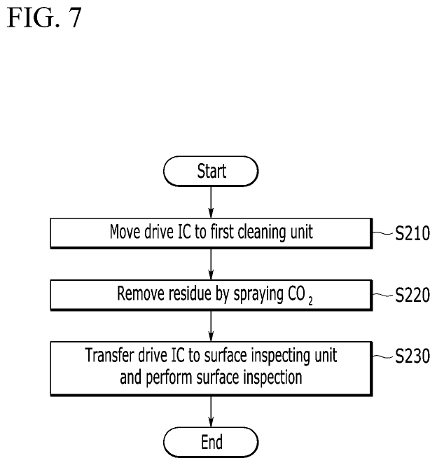

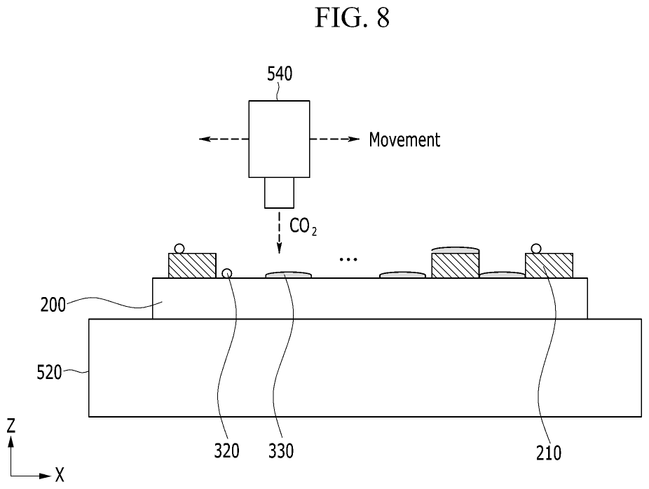

The first cleaning unit 12 may perform CO₂ cleaning on the drive IC 200. A detailed description of the CO₂ cleaning process will be given below with reference to FIGS. 7 and 8.

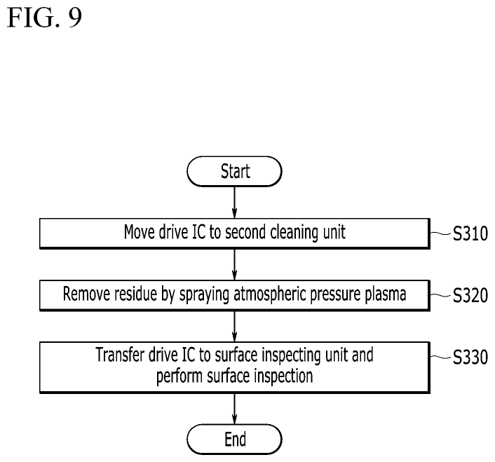

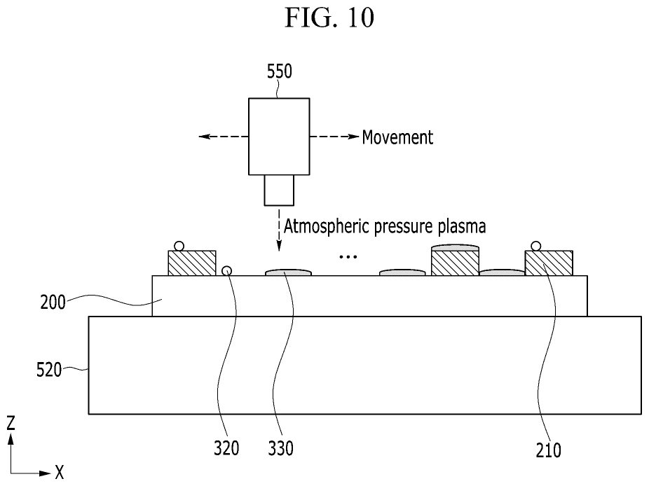

The second cleaning unit 13 may perform atmospheric pressure plasma cleaning on the drive IC 200. A detailed description of the atmospheric pressure plasma cleaning process will be given below with reference to FIGS. 9 and 10.

The surface inspecting unit 14 may perform surface inspection on the drive IC 200 after the CO₂ cleaning or the atmospheric pressure plasma cleaning. The surface inspecting unit 14 may inspect residues remaining on the drive IC 200 by using an optical microscope, a camera, or the like by means of an auto-visual inspection (AVI) method. The surface inspecting unit 14 may determine quality product determination, defective product determination, additional cleaning determination, and the like depending on a surface inspection result. That is, the surface inspecting unit 14 may determine the quality product determination when the amount of residues remaining on the drive IC 200 is equal to or less than a preset reference value. When the amount of residues remaining on the drive IC 200 exceeds the reference value, the surface inspecting unit 14 may determine the defective product determination or the additional cleaning determination so that the CO₂ cleaning or the atmospheric pressure plasma cleaning may be additionally performed. In this case, the surface inspecting unit 14 may determine the additional cleaning determination until the number of times of cleaning reaches a predetermined number of times of cleaning. The surface inspecting unit 14 may finally determine the drive IC 200 as a defective product when the amount of residues remaining on the drive IC 200 exceeds the reference value even when the number of times the CO₂ cleaning and the atmospheric pressure plasma cleaning are performed on the drive IC 200 reaches the predetermined number of times of cleaning.

The drive IC sorting unit 15 sorts the drive IC 200 as a quality product or a defective product depending on the quality product determination or the defective product determination of the surface inspecting unit 14 and loads the drive IC 200 on a quality product tray or a defective product tray.

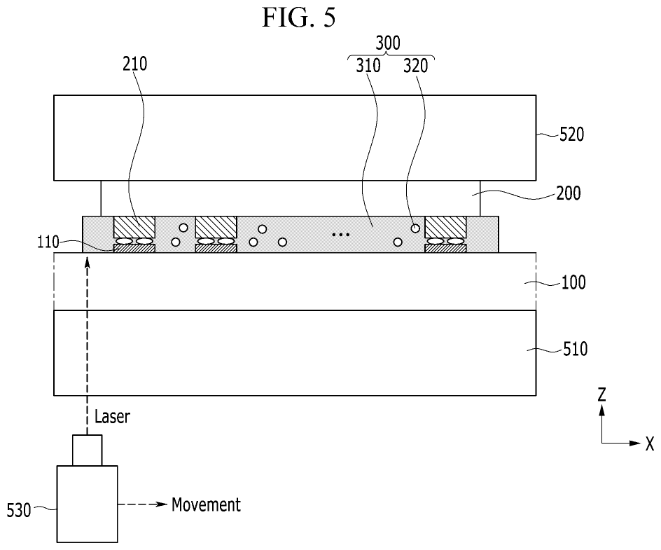

The drive IC separating unit 11 and the first cleaning unit 12 may be connected by a first rail 21, and the drive IC 200 separated from the drive IC separating unit 11 may be loaded onto a drive IC stage (see 520 in FIG. 5) and transferred to the first cleaning unit 12 through the first rail 21.

The drive IC separating unit 11 and the second cleaning unit 13 may be connected by a second rail 22, and the drive IC 200 separated from the drive IC separating unit 11 may be loaded onto the drive IC stage 520 and transferred to the second cleaning unit 13 through the second rail 22.

The first cleaning unit 12 and the surface inspecting unit 14 may be connected by a third rail 23, and the drive IC 200, on which the CO₂ cleaning has been performed by the first cleaning unit 12, may be loaded onto the drive IC stage 520 and transferred to the surface inspecting unit 14 through the third rail 23. Further, the drive IC 200, on which the surface inspection has been performed by the surface inspecting unit 14, may be loaded onto the drive IC stage 520 and transferred to the first cleaning unit 12 through the third rail 23. The second cleaning unit 13 and the surface inspecting unit 14 may be connected by a fourth rail 24, and the drive IC 200, on which the atmospheric pressure plasma cleaning process has been performed by the second cleaning unit 13, may be loaded onto the drive IC stage 520 and transferred to the surface inspecting unit 14 through the fourth rail 24. Further, the drive IC 200, on which the surface inspection has been performed by the surface inspecting unit 14, may be loaded onto the drive IC stage 520 and transferred to the second cleaning unit 13 through the fourth rail 24.

The first cleaning unit 12 and the second cleaning unit 13 may be connected by a fifth rail 25. The drive IC 200, on which the CO₂ cleaning has been performed by the first cleaning unit 12, may be loaded onto the drive IC stage 520 and transferred to the second cleaning unit 13 through the fifth rail 25. The drive IC 200, on which the atmospheric pressure plasma cleaning has been performed by the second cleaning unit 13, may be loaded onto the drive IC stage 520 and transferred to the first cleaning unit 12 through the fifth rail 25.

As described above, the drive IC separating unit 11, the first cleaning unit 12, the second cleaning unit 13, and the surface inspecting unit 14 may be connected to one another by the plurality of rails 21, 22, 23, 24, and 25. Therefore, the dry cleaning apparatus 10 for recycling the drive IC may perform the dry cleaning on the drive IC 200 in the order of the cleaning and the surface inspection in various ways.

For example, first CO₂ cleaning, atmospheric pressure plasma cleaning, and second CO₂ cleaning may be sequentially performed on the drive IC 200 separated from the display panel or the flexible printed circuit board by the drive IC separating unit 11. In this case, the surface inspection on the drive IC 200 may be performed after each of the first CO₂ cleaning, the atmospheric pressure plasma cleaning, and the second CO₂ cleaning or performed once in the last order.

Alternatively, the atmospheric pressure plasma cleaning is performed after the CO₂ cleaning is performed on the drive IC 200 separated from the display panel or the flexible printed circuit board by the drive IC separating unit 11, such that the cleaning process may be ended. Alternatively, the CO₂ cleaning is performed after the atmospheric pressure plasma cleaning is performed, such that the cleaning process may be ended. In this case, the surface inspection on the drive IC 200 may be performed after each of the CO₂ cleaning and the atmospheric pressure plasma cleaning or performed once in the last order.

Alternatively, the atmospheric pressure plasma cleaning process is performed on the drive IC 200 separated from the display panel or the flexible printed circuit board by the drive IC separating unit 11, and when the quality product determination is not determined during the surface inspection on the drive IC 200, the atmospheric pressure plasma cleaning process may be repeatedly performed a predetermined number of times of cleaning.

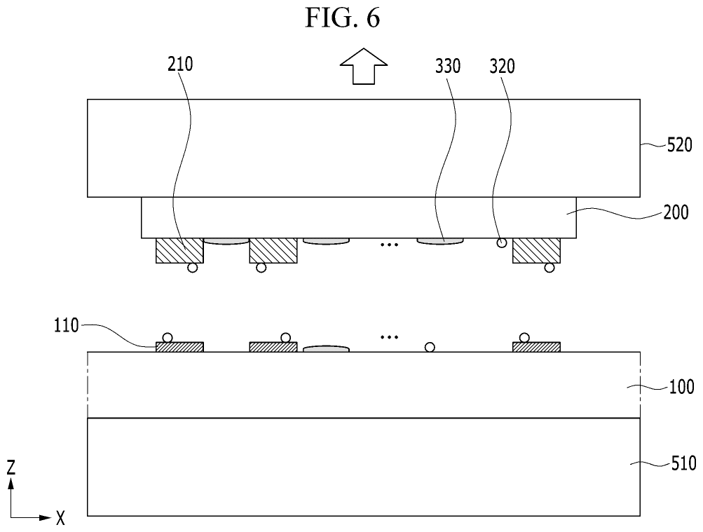

FIG. 4 is a flowchart illustrating a method of performing a process of separating the drive IC according to the embodiment of the present disclosure. FIGS. 5 and 6 are cross-sectional views for explaining the method of performing the process of separating the drive IC according to the embodiment of the present disclosure.

With reference to FIGS. 4 to 6, the drive IC separating unit 11 may include a display panel stage 510, the drive IC stage 520, and a laser source 530.

The display panel stage 510 may be configured to support and fix the display panel and the drive IC 200.

The drive IC stage 520 may be positioned on the drive IC 200 and serve to fix the display panel and the drive IC 200, block laser beams emitted to a bottom surface of the display panel stage 510, suck, separate, and transfer the drive IC 200, and fix the drive IC 200 during the process of cleaning the drive IC 200.

The display panel is aligned and positioned on the display panel stage 510 (S110). The display panel, which is in the state in which the drive IC 200 is joined to the substrate 100 by the anisotropic conductive film 300, may be aligned and disposed at a predetermined position on the display panel stage 510. In this case, the drive IC stage 520 may push the display panel with a pressure that may fix the display panel to which the drive IC 200 is joined, thereby preventing the display panel from deviating from the predetermined position.

The laser source 530 positioned below the display panel stage 510 emits laser beams and selectively combusts the adhesive resin 310 (S120). The laser source 530 may emit laser beams having a low absorption rate to the bump 210 of the drive IC 200, the pad 110 of the substrate 100, and the metal line, having a high absorption rate to the adhesive resin 310 of the anisotropic conductive film 300, and being capable of passing through the substrate 100. The laser beams may include laser beams with wavelengths of near infrared (NIR) rays or infrared (IR) rays. According to the embodiment, the laser beams within wavelength ranges of green rays and ultraviolet rays may be used, and continuous wave laser beams, pulsed laser beams, and the like may be used. The laser source 530 may emit laser beams in the third direction Z (vertical direction) toward the anisotropic conductive film 300 while moving in the horizontal direction. The laser beams may pass through the display panel stage 510 and the substrate 100 and be absorbed only by the adhesive resin 310 of the anisotropic conductive film 300. The adhesive resin 310 of the anisotropic conductive film 300, which absorbs energy of the laser beams, is combusted and completely loses a bonding force.

The adhesive resin 310 is combusted and loses a bonding force, ash 330 made by combustion of the adhesive resin 310 and the conductive particles 320, which are not combusted, remain as residues, and the drive IC 200 may be separated from the display panel (S130). The drive IC stage 520 may suck the drive IC 200 and move in the third direction Z, such that the drive IC 200 may be separated from the display panel. Because the adhesive resin 310 loses the bonding force, no direct physical force is applied to the display panel and the drive IC 200. Therefore, the display panel and the drive IC 200 may be separated without damage.

FIG. 7 is a flowchart illustrating a method of performing a CO₂ cleaning process according to the embodiment of the present disclosure. FIG. 8 is a cross-sectional view for explaining the method of performing the CO₂ cleaning process according to the embodiment of the present disclosure.

With reference to FIGS. 7 and 8, the drive IC 200 separated from the display panel may be moved from the drive IC separating unit 11 to the first cleaning unit 12 (S210). In this case, the drive IC 200 may be loaded onto the drive IC stage 520 and transferred to the first cleaning unit 12 through the first rail 21. In some instances, the drive IC 200 may be moved from the second cleaning unit 13 to the first cleaning unit 12. In this case, the drive IC 200 may be loaded onto the drive IC stage 520 and transferred to the first cleaning unit 12 through the fifth rail 25.

The first cleaning unit 12 may include a first sprayer 540. The first sprayer 540 may spray CO₂ toward the drive IC 200 positioned on the drive IC stage 520, thereby removing residues of the anisotropic conductive film 300 (S220). The first sprayer 540 may spray CO₂ while repeatedly moving in the first direction X (or the second direction Y or the horizontal direction) for about 30 to 60 seconds in the third direction Z (vertical direction) at a height of 15 to 25 mm in the third direction Z (or the vertical direction) from the surface of the drive IC 200, thereby removing residues of the anisotropic conductive film 300. The first sprayer 540 may also spray dry ice particles, which is solid CO₂, and carrier gas (N₂ or clean dry air (CDA)), thereby removing residues of the anisotropic conductive film 300. The first sprayer 540 may directly spray dry ice pellets or convert liquid carbon dioxide into solid carbon dioxide and then spray the solid carbon dioxide. Sizes (diameters) of dry ice particles sprayed from the first sprayer 540, an interval between the first sprayer 540 and the surface of the drive IC 200, a CO₂ spray pressure, a CO₂ spray angle, a CO₂ spray time, and the like may be variously changed and set. Therefore, a contact area of CO₂ and a cleaning speed may be changed. For example, the dry ice particle may have a size smaller than an interval between the plurality of bumps 210. For example, in case that the interval between the plurality of bumps 210 is large, the first sprayer 540 may spray dry ice particles each having a size of about 150 μm. In case that a fine interval is set between the plurality of bumps 210, the first sprayer 540 may spray dry ice particles each having a size of 1 to 10 μm. Therefore, it is possible to improve the cleaning effect. The CO₂ cleaning may not only perform a cleaning function of removing residues of the anisotropic conductive film 300, but also a function of reducing heat generated by laser beams.

In this case, the example has been described in which the first sprayer 540 may spray CO₂ while moving in the first direction X (or the second direction Y or the horizontal direction). However, according to the embodiment, the first sprayer 540 may be fixed and spray CO₂, and the drive IC stage 520 for transferring the drive IC 200 may repeatedly move in the first direction X (or the second direction Y or the horizontal direction), such that the CO₂ cleaning may be performed.

Next, the drive IC 200 may be transferred from the first cleaning unit 12 to the surface inspecting unit 14, and the surface inspecting unit 14 may perform the surface inspection on the drive IC 200 (S230). The drive IC 200 may be loaded onto the drive IC stage 520 and transferred to the surface inspecting unit 14 through the third rail 23. The surface inspecting unit 14 may inspect residues remaining on the drive IC 200 by using an optical microscope, a camera, or the like.

FIG. 9 is a flowchart illustrating a method of performing an atmospheric pressure plasma cleaning process according to the embodiment of the present disclosure. FIG. 10 is a cross-sectional view for explaining the method of performing the atmospheric pressure plasma cleaning process according to the embodiment of the present disclosure.

With reference to FIGS. 9 and 10, the drive IC 200 separated from the display panel may be moved from the drive IC separating unit 11 to the second cleaning unit 13 (S310). In this case, the drive IC 200 may be loaded onto the drive IC stage 520 and transferred to the second cleaning unit 13 through the second rail 22. In some instances, the drive IC 200 may be moved from the first cleaning unit 12 to the second cleaning unit 13. In this case, the drive IC 200 may be loaded onto the drive IC stage 520 and transferred to the second cleaning unit 13 through the fifth rail 25.

The second cleaning unit 13 may include a second sprayer 550. The second sprayer 550 may spray (discharge) atmospheric pressure plasma toward the drive IC 200 positioned on the drive IC stage 520, thereby removing residues of the anisotropic conductive film 300 (S320). The second sprayer 550 may supply clean dry air (CDA) or nitrogen N₂ at a pressure of 2.5 bar and spray (discharge) atmospheric pressure plasma while repeatedly moving in the first direction X (or the second direction Y or the horizontal direction) for about 30 to 60 seconds at a height of 15 to 50 mm in the third direction Z (or the vertical direction) from the surface of the drive IC 200, thereby removing residues of the anisotropic conductive film 300. The second sprayer 550 may discharge the atmospheric pressure plasma with an output of about 100 to 1,000 W in an arc-jet or direct manner. An interval between the second sprayer 550 and the surface of the drive IC 200, a range of atmospheric pressure plasma, a discharge voltage of atmospheric pressure plasma, a discharge frequency of atmospheric pressure plasma, a nozzle size of the second sprayer 550, a temperature of atmospheric pressure plasma, a movement speed of the second sprayer 550, and the like may be variously changed and set. Therefore, a cleaning speed implemented by the atmospheric pressure plasma may be changed.

The CO₂ cleaning has an effect of removing residues such as ash 330 made by the combustion of the adhesive resin 310 and the non-combusted conductive particles 320, whereas the atmospheric pressure plasma cleaning has an effect of removing residues, removing organic materials remaining on the surface of the drive IC 200, and flattening the surface of the drive IC 200.

In this case, the example has been described in which the second sprayer 550 sprays (discharges) atmospheric pressure plasma while moving in the first direction X (or the second direction Y or the horizontal direction). However, according to the embodiment, the second sprayer 550 may be fixed and spray (discharge) the atmospheric pressure plasma, and the drive IC stage 520 for transferring the drive IC 200 may repeatedly move in the first direction X (or the second direction Y or the horizontal direction), such that the atmospheric pressure plasma cleaning may be performed.

Next, the drive IC 200 may be transferred from the second cleaning unit 13 to the surface inspecting unit 14, and the surface inspecting unit 14 may perform the surface inspection on the drive IC 200 (S330). The drive IC 200 may be loaded onto the drive IC stage 520 and transferred to the surface inspecting unit 14 through the fourth rail 24. The surface inspecting unit 14 may inspect residues remaining on the drive IC 200 by using an optical microscope, a camera, or the like.

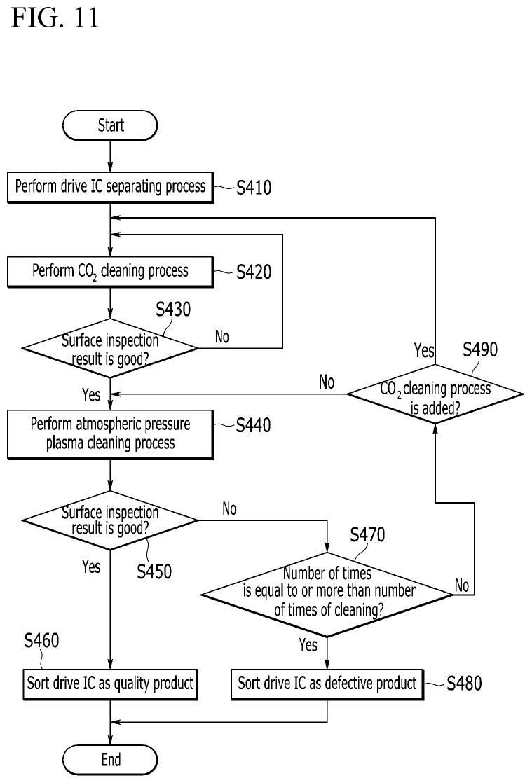

Hereinafter, embodiments in which the dry cleaning apparatus 10 for recycling the drive IC performs the dry cleaning on the drive IC 200 in various ways in the order of the cleaning and the surface inspection will be described with reference to FIGS. 11 to 15.

FIG. 11 is a flowchart illustrating a dry cleaning method for recycling a drive IC according to the embodiment of the present disclosure.

With reference to FIG. 11, the dry cleaning apparatus 10 may perform the drive IC separating process of separating the drive IC 200 from the display panel or the flexible printed circuit board (S410). The drive IC separating process may be performed as described above with reference to FIGS. 4 to 6.

The dry cleaning apparatus 10 may perform the CO₂ cleaning process by moving the drive IC 200, which is separated from the display panel, from the drive IC separating unit 11 to the first cleaning unit 12, removing residues of the anisotropic conductive film 300 by spraying CO₂ toward the drive IC 200 by the first cleaning unit 12, transferring the drive IC 200 from the first cleaning unit 12 to the surface inspecting unit 14, and performing the surface inspection on the drive IC 200 (S420). The CO₂ cleaning process may be performed as described above with reference to FIGS. 7 and 8.

The dry cleaning apparatus 10 determines whether the surface inspection result is good S430. That is, the surface inspecting unit 14 may determine whether the amount of residues remaining on the drive IC 200 is equal to or less than a first reference value in first surface inspection on the drive IC 200 after the CO₂ cleaning.

The dry cleaning apparatus 10 may repeatedly perform the CO₂ cleaning process when the amount of residues remaining on the drive IC 200 exceeds the first reference value. That is, in case that the amount of residues remaining on the drive IC 200 exceeds the first reference value, the drive IC 200 may be loaded onto the drive IC stage 520 and transferred to the first cleaning unit 12 through the third rail 23, and the CO₂ cleaning process may be repeatedly performed.

In case that the amount of residues remaining on the drive IC 200 is equal to or less than the first reference value and the surface inspection result is good during the surface inspection on the drive IC 200 after the CO₂ cleaning process, the dry cleaning apparatus 10 may perform the atmospheric pressure plasma cleaning process by moving the drive IC 200 from the surface inspecting unit 14 to the second cleaning unit 13, removing residues of the anisotropic conductive film 300 by spraying atmospheric pressure plasma toward the drive IC 200 by the second cleaning unit 13, transferring the drive IC 200 from the second cleaning unit 13 toward the surface inspecting unit 14, and performing the surface inspection on the drive IC 200 (S440). The atmospheric pressure plasma cleaning process may be performed as described above with reference to FIGS. 9 and 10.

The dry cleaning apparatus 10 determines whether the second surface inspection result after the atmospheric pressure plasma cleaning is good (S450). That is, the surface inspecting unit 14 may determine whether the amount of residues remaining on the drive IC 200 is equal to or less than a second reference value during the surface inspection on the drive IC 200 after the atmospheric pressure plasma cleaning.

The dry cleaning apparatus 10 may determine the drive IC 200 as a quality product when the amount of residues remaining on the drive IC 200 is equal to or less than the second reference value. The drive IC 200, which is determined as a quality product, may be sorted as a quality product by the drive IC sorting unit 15 and loaded into the quality product tray (S460).

In case that the amount of residues remaining on the drive IC 200 exceeds the second reference value during the second surface inspection on the drive IC 200 after the atmospheric pressure plasma cleaning process, the dry cleaning apparatus 10 may identify whether the number of times the CO₂ cleaning process and the atmospheric pressure plasma cleaning process are performed on the drive IC 200 up to now is equal to or more than a predetermined number of times of cleaning (S470).

In case that the CO₂ cleaning process and the atmospheric pressure plasma cleaning process have been performed the predetermined number of times of cleaning, the dry cleaning apparatus 10 may determine the drive IC 200 as a defective product, and the drive IC 200, which is determined as a defective product, may be sorted as a defective product by the drive IC sorting unit 15 and loaded into the defective product tray (S480).

In case that the CO₂ cleaning process and the atmospheric pressure plasma cleaning process have not been performed the predetermined number of times of cleaning, the dry cleaning apparatus 10 may determine whether to add the CO₂ cleaning process (S490). When the addition of the CO₂ cleaning process is required, the CO₂ cleaning process (S420) may be additionally performed. When the addition of the CO₂ cleaning process is not required, the atmospheric pressure plasma cleaning process (S440) may be additionally performed. Whether to add the CO₂ cleaning process may be determined depending on properties of residues such as the residual amount of ash 330, the residual amount of the conductive particles 320, and the residual amount of other organic materials according to the surface inspection result.

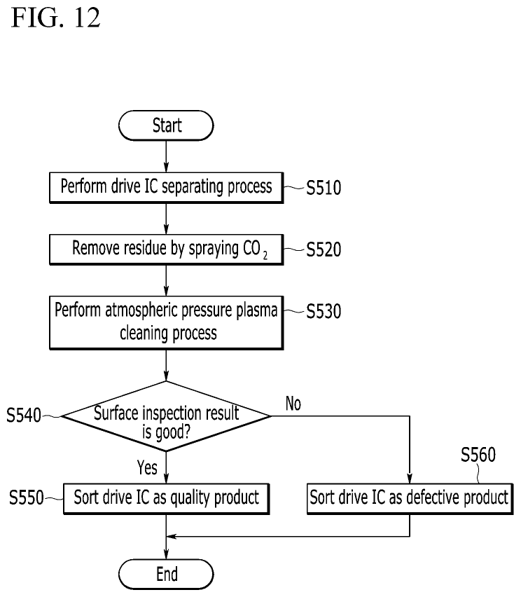

FIG. 12 is a flowchart illustrating a dry cleaning method for recycling a drive IC according to another embodiment of the present disclosure.

With reference to FIG. 12, the dry cleaning apparatus 10 may perform the drive IC separating process of separating the drive IC 200 from the display panel or the flexible printed circuit board (S510). The drive IC separating process may be performed as described above with reference to FIGS. 4 to 6.

The dry cleaning apparatus 10 may move the drive IC 200, which is separated from the display panel, from the drive IC separating unit 11 to the first cleaning unit 12 and remove residues of the anisotropic conductive film 300 by spraying CO₂ toward the drive IC 200 by the first cleaning unit 12 (S520). This process may be performed like the processes S210 and S220 as described above with reference to FIGS. 7 and 8.

The dry cleaning apparatus 10 may perform the atmospheric pressure plasma cleaning process by transferring the drive IC 200 from the first cleaning unit 12 toward the second cleaning unit 13, removing residues of the anisotropic conductive film 300 by spraying atmospheric pressure plasma toward the drive IC 200, transferring the drive IC 200 from the second cleaning unit 13 to the surface inspecting unit 14, and performing the surface inspection on the drive IC 200 (S530). The atmospheric pressure plasma cleaning process may be performed as described above with reference to FIGS. 9 and 10.

The dry cleaning apparatus 10 determines whether the surface inspection result is good S540. That is, the surface inspecting unit 14 may determine whether the amount of residues remaining on the drive IC 200 is equal to or less than a reference value during the surface inspection on the drive IC 200 after the atmospheric pressure plasma cleaning process.

The dry cleaning apparatus 10 may determine the drive IC 200 as a quality product when the amount of residues remaining on the drive IC 200 is equal to or less than the reference value. The drive IC 200, which is determined as a quality product, may be sorted as a quality product by the drive IC sorting unit 15 and loaded into the quality product tray (S550).

The dry cleaning apparatus 10 may determine the drive IC 200 as a defective product when the amount of residues remaining on the drive IC 200 exceeds the reference value, and the drive IC 200 determined as a defective product may be sorted as a defective product by the drive IC sorting unit 15 and loaded into the defective product tray (S560).

The dry cleaning method according to the embodiment in FIG. 12 refers to a method of performing the CO₂ cleaning and the atmospheric pressure plasma cleaning once, performing the surface inspection, and then sorting the drive IC 200 as a quality product or a defective product. The dry cleaning method may more quickly perform the process of recycling the drive IC 200 in comparison with the embodiment in FIG. 11.

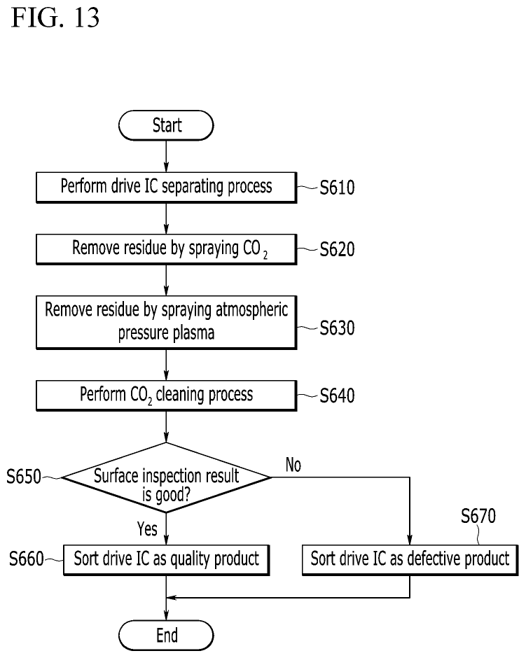

FIG. 13 is a flowchart illustrating a dry cleaning method for recycling a drive IC according to still another embodiment of the present disclosure.

With reference to FIG. 13, the dry cleaning apparatus 10 may perform the drive IC separating process of separating the drive IC 200 from the display panel or the flexible printed circuit board (S610). The drive IC separating process may be performed as described above with reference to FIGS. 4 to 6.

The dry cleaning apparatus 10 may move the drive IC 200, which is separated from the display panel, from the drive IC separating unit 11 to the first cleaning unit 12 and remove residues of the anisotropic conductive film 300 by spraying CO₂ toward the drive IC 200 by the first cleaning unit 12 (S620). This process may be performed like the processes S210 and S220 as described above with reference to FIGS. 7 and 8.

The dry cleaning apparatus 10 may transfer the drive IC 200 from the first cleaning unit 12 to the second cleaning unit 13 and remove residues of the anisotropic conductive film 300 by spraying atmospheric pressure plasma toward the drive IC 200 (S630). This process may be performed like the processes S310 and S320 as described above with reference to FIGS. 9 and 10.

The dry cleaning apparatus 10 may perform the CO₂ cleaning process by transferring the drive IC 200 from the second cleaning unit 13 to the first cleaning unit 12, removing residues of the anisotropic conductive film 300 by spraying CO₂ toward the drive IC 200 by the first cleaning unit 12, transferring the drive IC 200 from the first cleaning unit 12 to the surface inspecting unit 14, and performing the surface inspection on the drive IC 200 (S640). The CO₂ cleaning process may be performed as described above with reference to FIGS. 7 and 8.

The dry cleaning apparatus 10 determines whether the surface inspection result is good (S650). That is, the surface inspecting unit 14 may determine whether the amount of residues remaining on the drive IC 200 is equal to or less than a reference value during the surface inspection on the drive IC 200 after the CO₂ cleaning process.

The dry cleaning apparatus 10 may determine the drive IC 200 as a quality product when the amount of residues remaining on the drive IC 200 is equal to or less than the reference value. The drive IC 200, which is determined as a quality product, may be sorted as a quality product by the drive IC sorting unit 15 and loaded into the quality product tray (S660).

The dry cleaning apparatus 10 may determine the drive IC 200 as a defective product when the amount of residues remaining on the drive IC 200 exceeds the reference value, and the drive IC 200 determined as a defective product may be sorted as a defective product by the drive IC sorting unit 15 and loaded into the defective product tray (S670).

The dry cleaning method according to the embodiment in FIG. 13 refers to a method of performing the first CO₂ cleaning, the atmospheric pressure plasma cleaning, and the second CO₂ cleaning once, performing the surface inspection, and then sorting the drive IC 200 as a quality product or a defective product. The dry cleaning method may add the cleaning process once in comparison with the embodiment in FIG. 12, thereby improving cleaning efficiency while slightly increasing the process time.

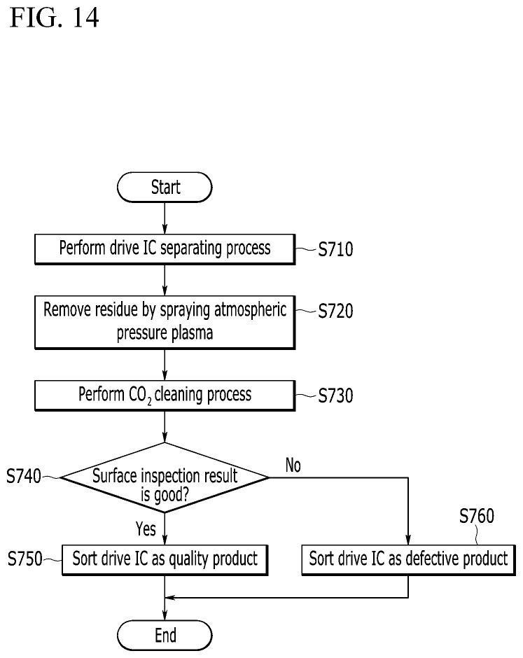

FIG. 14 is a flowchart illustrating a dry cleaning method for recycling a drive IC according to yet another embodiment of the present disclosure.

With reference to FIG. 14, the dry cleaning apparatus 10 may perform the drive IC separating process of separating the drive IC 200 from the display panel or the flexible printed circuit board (S710). The drive IC separating process may be performed as described above with reference to FIGS. 4 to 6.

The dry cleaning apparatus 10 may transfer the drive IC 200 from the drive IC separating unit 11 to the second cleaning unit 13 and remove residues of the anisotropic conductive film 300 by spraying atmospheric pressure plasma toward the drive IC 200 (S720). This process may be performed like the processes S310 and S320 as described above with reference to FIGS. 9 and 10.

The dry cleaning apparatus 10 may perform the CO₂ cleaning process by transferring the drive IC 200 from the second cleaning unit 13 to the first cleaning unit 12, removing residues of the anisotropic conductive film 300 by spraying CO₂ toward the drive IC 200 by the first cleaning unit 12, transferring the drive IC 200 from the first cleaning unit 12 to the surface inspecting unit 14, and performing the surface inspection on the drive IC 200 (S730). The CO₂ cleaning process may be performed as described above with reference to FIGS. 7 and 8.

The dry cleaning apparatus 10 determines whether the surface inspection result is good S740. That is, the surface inspecting unit 14 may determine whether the amount of residues remaining on the drive IC 200 is equal to or less than a reference value during the surface inspection on the drive IC 200 after the CO₂ cleaning process.

The dry cleaning apparatus 10 may determine the drive IC 200 as a quality product when the amount of residues remaining on the drive IC 200 is equal to or less than the reference value. The drive IC 200, which is determined as a quality product, may be sorted as a quality product by the drive IC sorting unit 15 and loaded into the quality product tray (S750).

The dry cleaning apparatus 10 may determine the drive IC 200 as a defective product when the amount of residues remaining on the drive IC 200 exceeds the reference value, and the drive IC 200 determined as a defective product may be sorted as a defective product by the drive IC sorting unit 15 and loaded into the defective product tray (S760).

The dry cleaning method according to the embodiment in FIG. 14 refers to a method of performing the atmospheric pressure plasma cleaning and the CO₂ cleaning once, performing the surface inspection, and sorting the drive IC 200 as a quality product or a defective product. The dry cleaning method may reduce the process time by reducing one CO₂ cleaning process in comparison with the embodiment in FIG. 13.

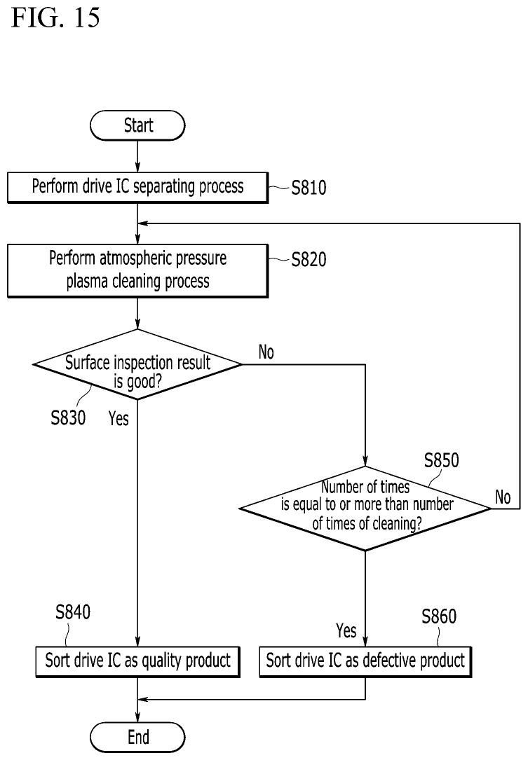

FIG. 15 is a flowchart illustrating a dry cleaning method for recycling a drive IC according to still yet another embodiment of the present disclosure.

With reference to FIG. 15, the dry cleaning apparatus 10 may perform the drive IC separating process of separating the drive IC 200 from the display panel or the flexible printed circuit board (S810). The drive IC separating process may be performed as described above with reference to FIGS. 4 to 6.

The dry cleaning apparatus 10 may perform the atmospheric pressure plasma cleaning process by transferring the drive IC 200 from the drive IC separating unit 11 toward the second cleaning unit 13, removing residues of the anisotropic conductive film 300 by spraying atmospheric pressure plasma toward the drive IC 200, transferring the drive IC 200 from the second cleaning unit 13 to the surface inspecting unit 14, and performing the surface inspection on the drive IC 200 (S820). The atmospheric pressure plasma cleaning process may be performed as described above with reference to FIGS. 9 and 10.

The dry cleaning apparatus 10 determines whether the surface inspection result is good S830. That is, the surface inspecting unit 14 may determine whether the amount of residues remaining on the drive IC 200 is equal to or less than a reference value during the surface inspection on the drive IC 200 after the atmospheric pressure plasma cleaning process.

The dry cleaning apparatus 10 may determine the drive IC 200 as a quality product when the amount of residues remaining on the drive IC 200 is equal to or less than the reference value. The drive IC 200, which is determined as a quality product, may be sorted as a quality product by the drive IC sorting unit 15 and loaded into the quality product tray (S840).

In case that the amount of residues remaining on the drive IC 200 exceeds the reference value during the surface inspection on the drive IC 200 after the atmospheric pressure plasma cleaning process, the dry cleaning apparatus 10 may identify whether the number of times the atmospheric pressure plasma cleaning process is performed on the drive IC 200 up to now is equal to or more than a predetermined number of times of cleaning (S850).

In case that the atmospheric pressure plasma cleaning process has been performed the predetermined number of times of cleaning, the dry cleaning apparatus 10 may determine the drive IC 200 as a defective product, and the drive IC 200, which is determined as a defective product, may be sorted as a defective product by the drive IC sorting unit 15 and loaded into the defective product tray (S860).

In case that the atmospheric pressure plasma cleaning process has not been performed the predetermined number of times of cleaning, the dry cleaning apparatus 10 may additionally perform the atmospheric pressure plasma cleaning process. That is, the dry cleaning apparatus 10 performs the processes again from step S820.

The dry cleaning method according to the embodiment in FIG. 14 refers to a method of performing the atmospheric pressure plasma cleaning process the predetermined number of times of cleaning without the CO₂ cleaning process and sorting the drive IC 200 as a quality product or a defective product.

The detailed description of the present disclosure described with reference to the drawings is just an example of the present disclosure. The description has been used for the purpose of explaining the present disclosure, but not used to limit the meaning or the scope of the present disclosure disclosed in the claims. Therefore, those skilled in the art will understand that various modifications of the embodiment and any other embodiment equivalent thereto are available. Accordingly, the true technical protection scope of the present disclosure should be determined by the technical spirit of the appended claims.

What is claimed is:

1. A dry cleaning apparatus comprising:
a drive IC separating unit configured to separate a drive device from a display panel or a flexible printed circuit board;
a first cleaning unit configured to remove residues of an anisotropic conductive film by performing CO₂ cleaning on the drive device;
a second cleaning unit configured to remove residues of the anisotropic conductive film by performing atmospheric pressure plasma cleaning on the drive device; and
a surface inspecting unit configured to perform surface inspection on the drive device after the CO₂ cleaning or the atmospheric pressure plasma cleaning.

2. The dry cleaning apparatus of claim 1, wherein:
the surface inspecting unit determines quality product determination when the amount of residues remaining on the drive device is equal to or less than a preset reference value, and the surface inspecting unit determines defective product determination or additional cleaning determination when the amount of residues remaining on the drive device exceeds the reference value.

3. The dry cleaning apparatus of claim 2, wherein:
the surface inspecting unit determines the additional cleaning determination until the number of times of cleaning reaches a predetermined number of times of cleaning, and the surface inspecting unit finally determines the drive device as a defective product when the amount of residues remaining on the drive device exceeds the reference value even when the number of times the CO₂ cleaning and the atmospheric pressure plasma cleaning are performed reaches the number of times of cleaning.

4. The dry cleaning apparatus of claim 1, wherein:
the drive IC separating unit comprises:
a drive IC stage configured to suck and transfer the drive device and fix the drive device at the time of cleaning the drive device; and
a laser source configured to selectively combust adhesive resin included in the anisotropic conductive film by emitting laser beams having a high absorption rate to the adhesive resin.

5. The dry cleaning apparatus of claim 1, wherein:
the first cleaning unit comprises:
a first sprayer configured to spray solid dry ice particles and carrier gas at a height from a surface of the drive device in a vertical direction.

6. The dry cleaning apparatus of claim 1, wherein:
the second cleaning unit comprises:
a second sprayer configured to discharge atmospheric pressure plasma at a height from a surface of the drive device in a vertical direction.

7. A dry cleaning method comprising:
separating, by a drive IC separating unit, a drive device from a display panel or a flexible printed circuit board;
removing, by a first cleaning unit, residues of an anisotropic conductive film by performing CO₂ cleaning on the drive device;
performing, by a surface inspecting unit, first surface inspection on the drive device after the CO₂ cleaning;
removing, by a second cleaning unit, residues of the anisotropic conductive film by performing atmospheric pressure plasma cleaning on the drive device; and
performing, by a surface inspecting unit, second surface inspection on the drive device after the atmospheric pressure plasma cleaning.

8. The dry cleaning method of claim 7, wherein:
the CO₂ cleaning is repeatedly performed when the amount of residues remaining on the drive device exceeds a preset first reference value during the first surface inspection.

9. The dry cleaning method of claim 7, wherein:
the surface inspecting unit determines the drive device as a quality product when the amount of residues remaining on the drive device is equal to or less than a preset second reference value in the second surface inspection, and the surface inspecting unit additionally performs the CO₂ cleaning or the atmospheric pressure plasma cleaning when the amount of residues remaining on the drive device exceeds the second reference value.

10. The dry cleaning method of claim 7, wherein:
the separating of the drive device comprises
selectively combusting adhesive resin included in the anisotropic conductive film by emitting laser beams having a high absorption rate to the adhesive resin.

11. The dry cleaning method of claim 7, wherein:
the removing of the residues of the anisotropic conductive film by performing the CO₂ cleaning on the drive device comprises
removing residues of the anisotropic conductive film by spraying solid dry ice particles and carrier gas at a height from a surface of the drive device in a vertical direction.

12. The dry cleaning method of claim 7, wherein:
the removing of the residues of the anisotropic conductive film by performing the atmospheric pressure plasma cleaning on the drive device comprises
removing residues of the anisotropic conductive film by discharging atmospheric pressure plasma at a height from a surface of the drive device in a vertical direction.

13. A dry cleaning method comprising:
separating, by a drive IC separating unit, a drive device from a display panel or a flexible printed circuit board;
removing, by a first cleaning unit, residues of an anisotropic conductive film by performing CO₂ cleaning on the drive device and then removing, by a second cleaning unit, residues of the anisotropic conductive film by performing atmospheric pressure plasma cleaning on the drive device; and
performing, by a surface inspecting unit, surface inspection on the drive device.
